(19) United States
(12) Patent Application Publication
(10) Pub. No.: US 2023/0420491 A1
(43) Pub. Date: Dec. 28, 2023

(54) Ferroelectric Film with Buffer Layers for Improved Reliability of Metal-Insulator-Metal Capacitor

(71) Applicant: International Business Machines Corporation, Armonk, NY (US)

(72) Inventors: Kisik Choi, Watervliet, NY (US); Paul Charles Jamison, Hopewell Junction, NY (US); Takashi Ando, Eastchester, NY (US); Lawrence A. Clevenger, Saratoga Springs, NY (US); Huimei Zhou, Albany, NY (US); Miaomiao Wang, Albany, NY (US); Ernest Y. Wu, Essex Junction, VT (US)

(21) Appl. No.: 17/851,290

(22) Filed: Jun. 28, 2022

(51) Int. Cl. H01L 49/02; H01L 29/51

(52) U.S. Cl. CPC H01L 28/75; H01L 28/65; H01L 28/91; H01L 29/516

(57) ABSTRACT

Metal-insulator-metal capacitor designs with increased reliability are provided. In one aspect, a capacitor includes: first and second electrodes; and multiple dielectric layers present in between the first and second electrodes, including a first buffer layer disposed on the first electrode, a ferroelectric film disposed on the first buffer layer, and a second buffer layer disposed on the ferroelectric film, where the ferroelectric film includes a combination of at least a first dielectric material and a second dielectric material having a higher κ value than either the first or second buffer layers. The first and second dielectric materials can each include HfO₂ and/or ZrO₂, in a crystalline phase, which can be combined in a common layer, or present in different layers. A capacitor device having the present capacitors stacked one on top of another is also provided, as is a method of forming the present capacitors.

### FIELD OF THE INVENTION

The present invention relates to metal-insulator-metal capacitors, and more particularly, to metal-insulator-metal capacitor designs having a ferroelectric film with buffer layers for improved reliability.

### BACKGROUND OF THE INVENTION

Metal-insulator-metal capacitors play a key role in many different integrated circuit architectures. An important consideration in any metal-insulator-metal capacitor design is achieving a sufficiently high capacitance per unit area. An increase in capacitance can be achieved by implementing a three-dimensional capacitor structure. For instance, with a three-dimensional capacitor structure, metal-insulator-metal capacitors can be stacked one on top of another. Doing so avoids expanding the overall footprint of the capacitor devices.

An increase in capacitance can also be achieved by using an insulator with a higher κ-value in the metal-insulator-metal capacitor design. While using a higher κ-value insulator in a standard metal-insulator-metal capacitor design is effective in boosting the capacitance, this approach can also undesirably lead to reliability issues.

For instance, use of a higher κ-value oxide insulator can potentially lead to an increase in both the initial leakage current and the stress induced leakage current. Stress induced leakage current is a measure of oxide trap defect buildup in an oxide material from electrical stress during use. Oxide breakdown can occur when the density of these oxide trap defects reaches a critical level. Thus, an increase in the stress induced leakage current can undesirably limit the lifetime of a metal-insulator-metal capacitor design.

### SUMMARY OF THE INVENTION

The present invention provides stackable metal-insulator-metal capacitor designs having a ferroelectric film with buffer layers which advantageously enables the use of a higher κ-value insulator while also mitigating both the initial leakage current and the stress induced leakage current. Therefore, the present metal-insulator-metal capacitor designs favorably provide an increase in capacitance per unit area without a tradeoff in reliability.

In one aspect of the invention, a capacitor is provided. The capacitor includes: a first electrode; a second electrode; and multiple dielectric layers present in between the first electrode and the second electrode, the multiple dielectric layers including a first buffer layer disposed on the first electrode, a ferroelectric film disposed on the first buffer layer, and a second buffer layer disposed on the ferroelectric film, where the ferroelectric film includes a combination of at least a first dielectric material and a second dielectric material having a higher dielectric constant κ value than either the first buffer layer or the second buffer layer.

For instance, the first buffer layer and the second buffer layer can each include aluminum oxide (Al₂O₃). The first dielectric material and the second dielectric material can each be selected from: hafnium oxide (HfO₂), zirconium oxide (ZrO₂), and combinations thereof, which can be in a crystalline phase selected from: a cubic phase, a tetragonal phase, an orthorhombic phase, and combinations thereof. The ferroelectric film can have a thickness of from about 4 nanometers (nm) to about 8 nm, which advantageously reduces the initial leakage current, while the first and second buffer layers mitigate stress induced leakage current.

In another aspect of the invention, another capacitor is provided. The capacitor includes: a first electrode; a second electrode; and multiple dielectric layers present in between the first electrode and the second electrode, the multiple dielectric layers including a first buffer layer disposed on the first electrode, a ferroelectric film disposed on the first buffer layer, and a second buffer layer disposed on the ferroelectric film, where the first buffer layer and the second buffer layer each includes Al₂O₃, and where the ferroelectric film includes both HfO₂ and ZrO₂ which can be in a crystalline phase selected from: a cubic phase, a tetragonal phase, an orthorhombic phase, and combinations thereof.

In yet another aspect of the invention, yet another capacitor is provided. The capacitor includes: a first electrode; a second electrode; and multiple dielectric layers present in between the first electrode and the second electrode, the multiple dielectric layers including a first buffer layer disposed on the first electrode, a ferroelectric film disposed on the first buffer layer, and a second buffer layer disposed on the ferroelectric film, where the first buffer layer and the second buffer layer each includes Al₂O₃, and where the ferroelectric film includes HfO₂ and ZrO₂ present in different layers. For instance, the ferroelectric film can include a first HfO₂ layer disposed on the first buffer layer; a ZrO₂ layer disposed on the first HfO₂ layer; and a second HfO₂ layer disposed on the ZrO₂ layer. Further, the first HfO₂ layer can have a thickness T1, the ZrO₂ layer can have a thickness T2, and the second HfO₂ layer can have a thickness T3, where T2 is greater than either T1 or T3.

In still yet another aspect of the invention, a capacitor device is provided. The capacitor device includes: a first capacitor; and a second capacitor stacked on top of the first capacitor, where the first capacitor and the second capacitor each includes a first electrode, a second electrode, and multiple dielectric layers present in between the first electrode and the second electrode, where the second electrode of the first capacitor is shared with the first electrode of the second capacitor, where the multiple dielectric layers include a first buffer layer disposed on the first electrode, a ferroelectric film disposed on the first buffer layer, and a second buffer layer disposed on the ferroelectric film, and where the ferroelectric film includes a combination of at least a first dielectric material and a second dielectric material having a higher dielectric constant κ value than either the first buffer layer or the second buffer layer. For instance, the first dielectric material and the second dielectric material can each include a material selected from: HfO₂, ZrO₂, and combinations thereof, which can be in a crystalline phase selected from: a cubic phase, a tetragonal phase, an orthorhombic phase, and combinations thereof.

In a further aspect of the invention, a method of forming a capacitor is provided. The method includes: forming multiple dielectric layers on a first electrode by depositing a first buffer layer on the first electrode, depositing a ferroelectric film on the first buffer layer, and depositing a second buffer layer on the ferroelectric film, where the ferroelectric film includes a combination of at least a first dielectric material and a second dielectric material having a higher dielectric constant κ value than either the first buffer layer or the second buffer layer; and forming a second electrode on the second buffer layer. The first dielectric material and the second dielectric material can be converted from an as-deposited amorphous phase to a crystalline phase selected from: a cubic phase, a tetragonal phase, an orthorhombic phase, and combinations thereof.

A more complete understanding of the present invention, as well as further features and advantages of the present invention, will be obtained by reference to the following detailed description and drawings.

### BRIEF DESCRIPTION OF THE DRAWINGS

FIG. 1 is a cross-sectional diagram illustrating an exemplary metal-insulator-metal capacitor according to an embodiment of the present invention;

FIG. 2 is a diagram illustrating an exemplary methodology for forming the present metal-insulator-metal capacitor according to an embodiment of the present invention;

FIG. 3 is a diagram illustrating the present metal-insulator-metal capacitor having a ferroelectric film that is configured as a single layer containing a mixture of hafnium oxide (HfO₂) and zirconium oxide (ZrO₂) according to an embodiment of the present invention;

FIG. 4 is a diagram illustrating the present metal-insulator-metal capacitor having a ferroelectric film that is configured to have HfO₂ and ZrO₂ present in different layers according to an embodiment of the present invention;

FIG. 5 is a diagram illustrating the present metal-insulator-metal capacitor having a ferroelectric film that is configured to have HfO₂ and a mixture of HfO₂ and ZrO₂ present in different layers according to an embodiment of the present invention; and

FIG. 6 is a diagram illustrating a stacked three-dimensional capacitor device according to an embodiment of the present invention.

### DETAILED DESCRIPTION OF PREFERRED EMBODIMENTS

As highlighted above, an important consideration in metal-insulator-metal capacitor designs is achieving a sufficiently high capacitance per unit area. While employing an insulator with a higher κ-value in a given metal-insulator-metal capacitor design can increase the capacitance, it can also undesirably lead to an increase in the initial leakage current and the stress induced leakage current, thereby diminishing reliability.

Advantageously, provided herein are stackable metal-insulator-metal capacitor designs that enable the use of a higher κ-value insulator while also mitigating both the initial leakage current and the stress induced leakage current. Thus, in addition to using a three-dimensional capacitor structure to increase capacitance per unit area, the present metal-insulator-metal capacitor designs also employ a higher κ-value insulator for increased capacitance without a tradeoff in reliability.

In general, a capacitor is a device that is used to store an electric charge. A metal-insulator-metal or MIM capacitor, as its name implies, includes an insulator in between metal electrodes. As will be described in detail below, the present metal-insulator-metal capacitor designs include an insulator that is formed from multiple dielectric layers. For instance, according to an exemplary embodiment, these multiple dielectric layers include a ferroelectric film sandwiched between at least two buffer layers. These dielectric layers act as an insulator and stop current from flowing through the capacitor. Namely, due to the polarization of charges on either side of the dielectric layers due to an applied electric field, the dielectric layers produce an electric field of their own which acts in a direction opposite to that of the applied electric field. As a result, a voltage is formed across the electrodes located on opposite sides of the dielectric layers in the form of an electrical charge.

According to an exemplary embodiment, the ferroelectric film has a higher κ-value than either of the buffer layers. The κ-value of a dielectric or dielectric constant is a measure of the electric permittivity of a dielectric material relative to the electric permittivity of a free space in a vacuum. For instance, silicon dioxide (SiO₂) has a κ-value of 3.9. Dielectrics having a κ-value greater than SiO₂ are often considered to be high-κ dielectrics, while dielectrics having a κ-value less than or equal to SiO₂ are often considered to be low-κ dielectrics.

Use of a higher-κ ferroelectric film increases the capacitance of the present metal-insulator-metal capacitor designs. As will be described in detail below, increasing the thickness of the ferroelectric film can be used to decrease the initial leakage current. However, that comes with the risk of degrading the stress induced leakage current due to current conduction via an increase in trap sites within the ferroelectric film. However, without being bound by any theory in particular, it is thought that implementing the lower-κ buffer layers to either side of the ferroelectric film serves to reduce the initial leakage due to a higher band gap, while not degrading the stress induced leakage current because the buffer layers make trap sites within the ferroelectric film inaccessible during electrical stress.

As will also be described in detail below, a variety of different embodiments are contemplated herein for the configuration of the ferroelectric film. For instance, by way of example only, in one or more embodiments the ferroelectric film includes a combination of high-κ dielectric materials such as hafnium oxide (HfO₂) and/or zirconium oxide (ZrO₂), arranged in multiple, distinct layers and/or intermixed within at least one common layer.

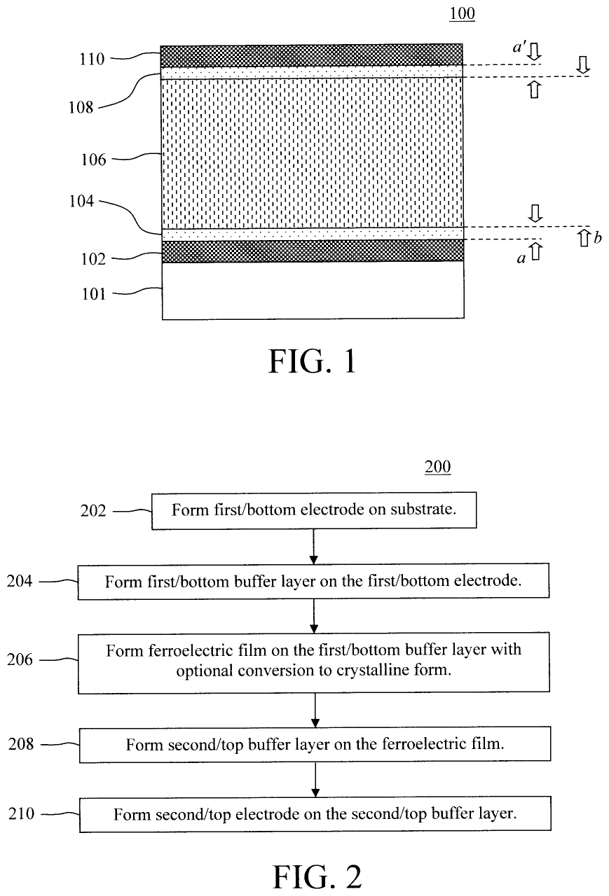

Given the above overview, FIG. 1 is a cross-sectional diagram illustrating an exemplary metal-insulator-metal capacitor 100 in accordance with the present techniques. For clarity and ease of depiction, the various features shown throughout the figures may not be drawn to scale. As shown in FIG. 1, metal-insulator-metal capacitor 100 includes a first (bottom) electrode 102 disposed on an inter-layer dielectric 101, a first (bottom) buffer layer 104 disposed on the first electrode 102, a ferroelectric film 106 disposed on the first buffer layer 104, a second (top) buffer layer 108 disposed on the ferroelectric film 106, and a second (top) electrode 110 disposed on the second (top) buffer layer 108. As shown in FIG. 1, by way of this configuration the ferroelectric film 106 is sandwiched between the first and second buffer layers 104 and 108.

Inter-layer dielectric 101 can generally include any dielectric material or combination of materials suitable for use in complementary metal-oxide semiconductor (CMOS) back-end-of-line (BEOL). For instance, by way of example only, suitable materials for inter-layer dielectric 101 include, but are not limited to, silicon nitride (SiN), oxide low-κ materials such as silicon oxide (SiOx) and/or ultralow-κ interlayer dielectric (ULK-ILD) materials, e.g., having a dielectric constant κ of less than 2.7. Suitable ultralow-κ dielectric materials include, but are not limited to, porous organosilicate glass (pSiCOH).

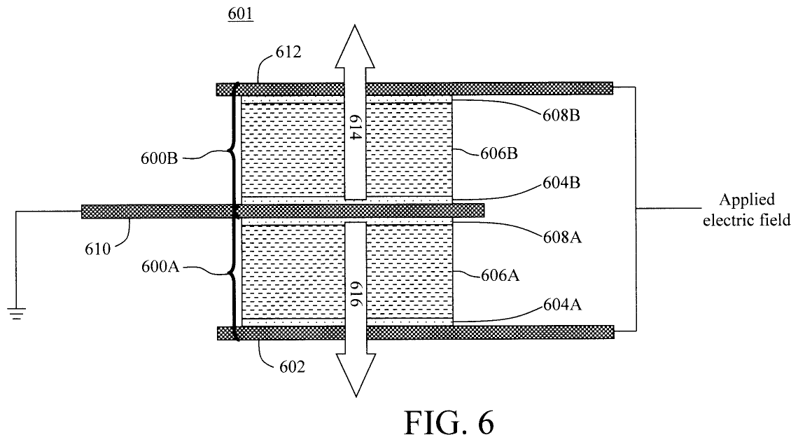

According to an exemplary embodiment, first and second electrodes 102 and 110 are each formed from a suitable metal and/or metal-containing compound such as, but not limited to, copper (Cu), nickel (Ni), platinum (Pt), palladium (Pd), aluminum (Al), tungsten (W), cobalt (Co), ruthenium (Ru), titanium (Ti), tantalum (Ta), titanium nitride (TiN), tantalum nitride (TaN) and combinations thereof. While FIG. 1 depicts the first and second electrodes 102 and 110 as having a same footprint as the other layers, this is merely one exemplary configuration. Namely, embodiments are contemplated herein and described in detail below where the first and second electrodes 102 and 110 are configured as plates that extend laterally out from the stack. See, e.g., the stacked capacitor design described in conjunction with the description of FIG. 6 below.

By way of example only, the first electrode 102 and the second electrode 110 can each have a thickness of from about 10 nanometers (nm) to about 40 nm and ranges therebetween. Further regarding a stacked capacitor design, as will be described below, when stacking one capacitor on top of another, the second/top electrode of the bottom capacitor is shared with the first/bottom electrode of the top capacitor.

In one exemplary embodiment, the first buffer layer 104 directly contacts the first electrode 102, and the second buffer layer 108 directly contacts the second electrode 110. It is notable that while the first buffer layer 104 and the second buffer layer 108 are each shown as a single layer, this is not a requirement. Namely, embodiments are also contemplated herein where first buffer layer 104 and/or second buffer layer 108 is/are composed of multiple layers.

As highlighted above, the present metal-insulator-metal capacitor designs include an insulator that is formed from multiple dielectric layers. The first buffer layer 104 and the second buffer layer 108 represent two (or more) of these multiple dielectric layers. Namely, first buffer layer 104 and second buffer layer 108 are each formed from a dielectric material. According to an exemplary embodiment, first buffer layer 104 and second buffer layer 108 are each formed from a lower-κ dielectric material than the ferroelectric film 106 (see below). By way of example only, suitable materials for first buffer layer 104 and second buffer layer 108 include, but are not limited to, aluminum oxide (Al₂O₃).

Very thin buffer layers are sufficient to make trap sites within the ferroelectric film 106 inaccessible. For instance, according to an exemplary embodiment, first and second buffer layers 104 and 108 have thicknesses a and a′, respectively, where a and a′ are each less than about 2 nm, e.g., thicknesses a and a′ of first and second buffer layers 104 and 108, respectively, are each from about 4 angstroms (Å) to about 10 Å and ranges therebetween. It is notable however that the configuration (e.g., composition, thickness, etc.) of the first and second buffer layers 104 and 108 does not have to be the same, and embodiments are contemplated herein where at least one of the composition and thickness varies between the first buffer layer 104 and the second buffer layer 108. In one exemplary embodiment, the first buffer layer 104 and the second buffer layer 108 each directly contacts the ferroelectric film 106. Ferroelectricity is the property of certain nonconductive crystals or dielectrics that exhibit spontaneous electric polarization, i.e., a separation of the center of positive and negative electric charge, the direction of which can be reversed by the application of an external electric field.

As highlighted above, the ferroelectric film 106 is formed from a higher-κ dielectric material(s) than the first and second buffer layers 104 and 108. Use of a high-κ dielectric material for the ferroelectric film 106 provides a higher capacitance, while the implementation of the first and second buffer layers 104 and 108 of a relatively lower-κ dielectric material helps to mitigate concerns related to stress induced leakage current, as described in detail above.

In general, the ferroelectric film 106 of metal-insulator-metal capacitor 100 includes a mixture of high-κ dielectric materials, arranged in one or more layers. Thus, while ferroelectric film 106 is generically depicted using one block in FIG. 1, scenarios are also contemplated herein where ferroelectric film 106 is made up of multiple layers. For instance, as will be described in detail below, while ferroelectric film 106 can be configured as a single layer, at least a portion of which contains a mixture of the high-κ dielectric materials, ferroelectric film 106 can alternatively include multiple layers each of which contains one of the high-κ dielectric materials or the other, or even a combination of the high-κ dielectric materials.

Suitable high-κ dielectric materials for ferroelectric film 106 include, but are not limited to, HfO₂, ZrO₂, and combinations thereof. Using a non-limiting example for illustrative purposes only, assume for instance that the first buffer layer 104 and the second buffer layer 108 are both formed from Al₂O₃. Al₂O₃ has a dielectric constant (κ) of from about 6 to about 9. By comparison, as-deposited amorphous HfO₂ or ZrO₂ has a dielectric constant (κ) of from about 18 to about 21, while the crystalline phases of HfO₂ or ZrO₂ can have a dielectric constant (κ) of from about 25 to about 40 (with the highest-κ phase being the cubic phase). The dielectric constant (κ) of these ferroelectric film 106 materials is significantly greater than that of the first/second buffer layer 104 and 108 materials. According to an exemplary embodiment, ferroelectric film 106 has a thickness b, where b is up to about 10 nm, e.g., thickness b of ferroelectric film 106 is from about 4 nm to about 8 nm and ranges therebetween.

Configurations are contemplated herein where the ferroelectric film 106 contains a combination of high-κ dielectric materials. For instance, by way of example only, according to one embodiment, the ferroelectric film 106 contains some combination of at least a first high-κ dielectric material and a second high-K dielectric material, such as HfO₂ and ZrO₂, respectively. For example, as will be described in detail below, the first and second high-κ dielectric materials can be present in separate layers that collectively form the ferroelectric film 106, the first and second high-κ dielectric materials can be mixed within a common layer and/or some combination thereof.

The use of a combination of high-κ dielectric materials can have some notable benefits. For instance, ZrO₂ is easier to crystallize into a higher-k phase than HfO₂. On the other hand, HfO₂ is more thermally stable than ZrO₂. Thus, a combination of HfO₂ and ZrO₂ can be used in accordance with the present techniques to achieve the benefits of both HfO₂ and ZrO₂.

Whether HfO₂ and ZrO₂ are present within separate layers or mixed within a common layer, it is preferable that the ratio of the number of hafnium (Hf) atoms to the number of zirconium (Zr) atoms throughout the ferroelectric film 106 is:

$$\frac{Zr}{( Hf + Zr )} \geq 0 \text{.50} . \qquad ( 1 )$$

Equation 1 is applied to total Hf and Zr counts, including the case where HfO₂ and ZrO₂ are present separately and/or combined in multiple layers. Further, from Equation 1 it can be seen that a scenario is possible where the number of Hf atoms in the ferroelectric film 106 is in fact zero (0). In that scenario, the ferroelectric film 106 contains only crystalline ZrO₂.

As deposited, high-κ dielectric materials such as HfO₂ and/or ZrO₂ are in an amorphous phase. However, ferroelectricity cannot be achieved with amorphous HfO₂ and/or ZrO₂. Thus, the high-κ dielectric materials used in the present ferroelectric film 106 are in a ferroelectric crystalline phase. For instance, in one exemplary embodiment, ferroelectric film 106 contains orthorhombic crystalline phase of HfO₂ and/or ZrO₂. Depending on the processing conditions, MX₂ twin oxide compounds like HfO₂ and ZrO₂ typically adopt the same crystalline structures. With the cubic crystalline phase of HfO₂ and ZrO₂, the oxygen atoms occupy all of the eight tetrahedral interstitial sites, and the hafnium and/or zirconium atoms occupy the regular sites of a face-centered cubic structure. This is also often referred to as a fluorite structure. With the tetragonal crystalline phase of HfO₂ and ZrO₂, each hafnium and/or zirconium atom is surrounded by eight oxygen atoms, four in a flattened tetrahedron and four in an elongated tetrahedron. The orthorhombic crystalline phase of HfO₂ and ZrO₂ can have space group Pca2₁.

The present metal-insulator-metal capacitor designs can be employed in a number of different applications. For instance, by way of example only, metal-insulator-metal capacitor 100 can be employed as a decoupling capacitor, an embedded dynamic random access memory or DRAM capacitor, a back-end-of line (BEOL) capacitor, and any combination thereof. A decoupling capacitor is generally used in an integrated circuit design to decouple one part of the circuit from another. If the input voltage increases or decreases, the decoupling capacitor serves to keep the voltage flowing through the circuit stable. Embedded DRAM or eDRAM refers to the embedding of a random access memory into an application-specific integrated circuit (ASIC), which can also include a microprocessor. DRAM stores each bit of data in a memory cell which can include a transistor and a capacitor. The capacitor can be either in a charged state or a discharged state, representing the bit values 0 or 1, respectively.

FIG. 2 is a diagram illustrating an exemplary methodology 200 for forming the present metal-insulator-metal capacitor 100 in accordance with the present techniques. In step 202, the first electrode 102 is formed on the substrate 101. As provided above, the first electrode 102 can be formed from a metal or metal-containing compound including, but not limited to, Cu, Ni, Pt, Pd, Al, W, Co, Ru, Ti, Ta, TiN, TaN and combinations thereof, which can be deposited onto substrate 101 using a process such as evaporation, sputtering or electrochemical plating. According to an exemplary embodiment, the first electrode 102 is formed having a thickness of from about 10 nm to about 40 nm and ranges therebetween.

An insulator is then formed on the first electrode 102. As provided above, the insulator in metal-insulator-metal capacitor 100 is formed from multiple dielectric layers that include ferroelectric film 106 sandwiched between the first buffer layer 104 and the second buffer layer 108. Thus, in step 204, formation of the insulator begins with the deposition of the first buffer layer 104 on the first electrode 102. As provided above, the first buffer layer 104 is formed from a lower-K dielectric material than the ferroelectric film 106. For example, a suitable dielectric material for the first buffer layer 104 includes, but is not limited to, Al₂O₃, which can be deposited onto the first electrode 102 using a process such as chemical vapor deposition (CVD), atomic layer deposition (ALD) or physical vapor deposition (PVD). As will be described in conjunction with the description of FIG. 6 below, when stacking one capacitor on top of another, the second/top electrode of the bottom capacitor is shared with the first/bottom electrode of the top capacitor. Thus, it may be the case that the first buffer layer is deposited on the shared electrode during formation of the top capacitor.

As provided above, very thin buffer layers are sufficient to make trap sites within the ferroelectric film 106 inaccessible. Thus, according to an exemplary embodiment, the first buffer layer 104 has a thickness a, where a is less than about 2 nm, e.g., thickness a of first buffer layer 104 is from about 4 angstroms (Å) to about 10 Å and ranges therebetween. In one illustrative, non-limiting example, ALD is used to deposit the first buffer layer 104 onto the first electrode 102. Advantageously, ALD enables the deposition of thin monolayers of the buffer layer material in a very precise manner. Multiple cycles are used to achieve the desired thickness. For instance, in this example, sub-monolayers of the first buffer layer 104 material, each having a thickness of less than (<) about 0.4 nm, are deposited using less than 5 ALD cycles. A monolayer is a layer of a material that is one molecule thick, and a sub-monolayer refers to one monolayer beneath another.

The next component of the insulator is the ferroelectric film 106 which, in step 206, is formed on the first buffer layer 104. As provided above, the ferroelectric film 106 is formed from higher-K dielectric materials than either the first buffer layer 104 or the second buffer layer 108. According to an exemplary embodiment, ferroelectric film 106 is formed from at least a first high-κ dielectric material and a second high-κ dielectric material combined amongst one or more layers. As provided above, suitable high-κ dielectric materials for ferroelectric film 106 include, but are not limited to, HfO₂, ZrO₂, and combinations thereof. Thus, in one embodiment, ferroelectric film 106 is formed by depositing one or more layers of HfO₂ as the first high-κ dielectric material and ZrO₂ as the second high-κ dielectric material on the first buffer layer 104.

As will be described in detail below, when the first/second high-κ dielectric materials are mixed within a common layer, the ferroelectric film 106 and first and second buffer layers 104 and 108 will have the configuration: first buffer layer/first high-κ dielectric material-second high-κ dielectric material mixture/second buffer layer. When the first/second high-κ dielectric materials are present in separate layers, the ferroelectric film 106 and first and second buffer layers 104 and 108 will have the configuration: first buffer layer/n distinct layers of the first high-κ dielectric material and the second high-κ dielectric material/second buffer layer. Combinations of these arrangements are also possible.

A process such as CVD, ALD or PVD can be employed to deposit the high-κ dielectric materials of ferroelectric film 106 onto the first buffer layer 104. By way of example only, when the high-κ dielectric materials HfO₂ and ZrO₂ are co-deposited in a single layer, a mixture of Hf and Zr alkoxide in a liquid can be employed for the vapor deposition. According to an exemplary embodiment, the ferroelectric film 106 has a thickness b, where b is up to about 10 nm, e.g., thickness b of ferroelectric film 106 is from about 4 nm to about 8 nm and ranges therebetween. Thus, when deposited as multiple layers, the combined thickness of the layers should equal thickness b.

As-deposited, the high-κ dielectric material(s) for ferroelectric film 106 such as HfO₂ and/or ZrO₂ are in an amorphous phase. A κ-value greater than 20 cannot be achieved with amorphous HfO₂ and/or ZrO₂. Thus, following deposition of the high-κ dielectric materials on the first buffer layer 104, the high-κ dielectric materials are then converted to a cubic, tetragonal and/or orthorhombic phase. As provided above, high-κ dielectric materials such as HfO₂ and/or ZrO₂ can have significantly higher dielectric constants (κ) in their crystalline form. For instance, an anneal can be performed to convert amorphous HfO₂ and ZrO₂ to a cubic phase, tetragonal phase and/or orthorhombic phase. By way of example only, an anneal performed at a temperature of from about 400 degrees Celsius (° C.) to about 450° C. and ranges therebetween can be used to form the orthorhombic phase of HfZrOₓ. Varying the anneal temperature and/or the film composition can produce the tetragonal or cubic phases of HfO₂ and ZrO₂. It is within the capabilities of a person of skill in the art to try different conditions and compositions, using known techniques, to produce these different phases of the materials. It is notable that this process may result in the formation of more than one of these phases of HfO₂ and ZrO₂ in the ferroelectric film 106. For instance, thermal treatment of the as-deposited film can result in a uniform cubic, tetragonal or orthorhombic phase throughout the ferroelectric film 106, or can instead result in a portion(s) of the ferroelectric film 106 having one of a cubic, tetragonal or orthorhombic phase while another portion(s) has a different one of these crystalline phases.

It is notable that the crystallization temperatures for HfO₂ and/or ZrO₂ provided above are low enough that the first/second Al₂O₃ buffer layers 104 and 108 are unaffected. Thus, the first/second buffer layers 104 and 108 remain in an as-deposited, amorphous phase.

Deposition of the second buffer layer 108 on the ferroelectric film 106 in step 208 completes the multi-layer insulator stack. As provided above, the second buffer layer 108 is formed from a lower-K dielectric material than the ferroelectric film 106. For example, a suitable dielectric material for the second buffer layer 108 includes, but is not limited to, Al₂O₃, which can be deposited onto the ferroelectric film 106 using a process such as CVD, ALD or PVD.

According to an exemplary embodiment, the second buffer layer 108 has a thickness a′, where a′ is less than about 2 nm, e.g., thickness a′ of second buffer layer 108 is from about 4 Å to about 10 Å and ranges therebetween. In one illustrative, non-limiting example, ALD is used to deposit the second buffer layer 108 onto the ferroelectric film 106. In this example, sub-monolayers of the second buffer layer 108 material, each having a thickness of less than (<) about 0.4 nm, are deposited using less than 5 ALD cycles.

In step 210, the second electrode 110 is formed on the second buffer layer 108. As provided above, the second electrode 110 can be formed from a metal or metal-containing compound including, but not limited to, Cu, Ni, Pt, Pd, Al, W, Co, Ru, Ti, Ta, TiN, TaN and combinations thereof, which can be deposited onto second buffer layer 108 using a process such as evaporation, sputtering or electrochemical plating. According to an exemplary embodiment, the second electrode 110 is formed having a thickness of from about 10 nm to about 40 nm and ranges therebetween.

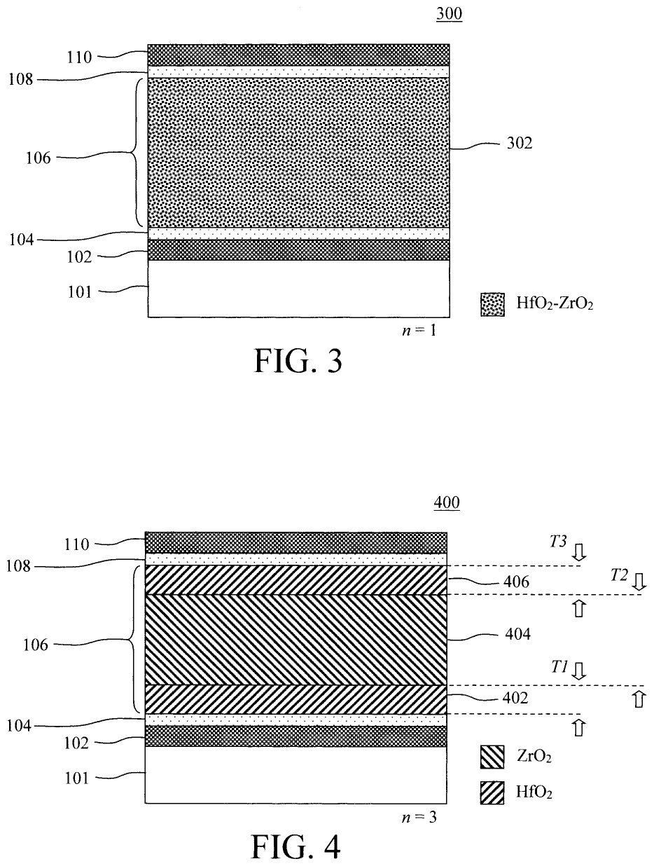

As provided above, the ferroelectric film 106 can be formed from at least a first high-κ dielectric material and a second high-κ dielectric material such as HfO₂ and ZrO₂, respectively, combined amongst one or more layers. In that regard, some possible configurations of ferroelectric film 106 are now described by way of reference to FIGS. 3-5. It is notable that the ferroelectric film 106 designs shown in FIGS. 3-5 are merely provided as illustrative examples, and do not represent an exhaustive list of all of the configurations that can be implemented for ferroelectric film 106 in accordance with the present techniques. It is also notable that like structures are numbered alike throughout the figures.

In the example shown illustrated in FIG. 3, a metal-insulator-metal capacitor 300 includes ferroelectric film 106 configured as a single layer 302 containing a mixture of HfO₂ and ZrO₂ (HfO₂—ZrO₂). Here, the number n of layers making up the ferroelectric film 106 is one, i.e., n=1. This configuration can be achieved by co-depositing HfO₂ and ZrO₂ as a single layer on the first buffer layer 104, followed by a thermal treatment (see above) to convert the as-deposited amorphous mixture to a (e.g., cubic, tetragonal and/or orthorhombic) crystalline phase. Preferably, the ratio of the number hafnium (Hf) atoms to the number of zirconium (Zr) atoms in the mixture is

$$\frac{Zr}{( Hf + Zr )} \geq 0 \text{.50} .$$

This includes a scenario where the number of Hf atoms in the mixture is zero (0). In that case, layer 302 of metal-insulator-metal capacitor 300 includes only (crystalline) ZrO₂.

Alternatively, HfO₂ and ZrO₂ can be present in different layers. See, for example, metal-insulator-metal capacitor 400 shown in FIG. 4. As shown in FIG. 4, metal-insulator-metal capacitor 400 includes ferroelectric film 106 configured as multiple layers 402, 404 and 406, i.e., n=3, with layer 402 containing HfO₂, layer 404 containing ZrO₂ and layer 406 containing HfO₂. This configuration can be achieved by first depositing a (first) layer of HfO₂ on the first buffer layer 104, depositing a layer of ZrO₂ on the layer of HfO₂, and then depositing another (second) layer of HfO₂ on the layer of ZrO₂, followed by a thermal treatment (see above) to convert the as-deposited amorphous materials to a (e.g., cubic, tetragonal and/or orthorhombic) crystalline phase. FIG. 4 further illustrates how the various component layers of ferroelectric film 106 can be of varying thicknesses. For instance, in this example, layer 402 has a thickness T1, layer 404 has a thickness T2, and layer 406 has a thickness T3, where T2 is greater than either T1 or T3. While, in this example, thickness T1 is equivalent to thickness T3 (T1=T3) this is not a requirement, and embodiments are contemplated herein where thickness T1 is different from thickness T3. However, the combined thickness of layers 402, 404 and 406 is preferably up to about 10 nm, e.g., from about 4 nm to about 8 nm and ranges therebetween. Employing a thicker layer 404 containing ZrO₂ ensures that the ratio of the number Hf atoms to the number of atoms amongst the layers 402, 404 and 406 is

$$\frac{Zr}{( Hf + Zr )} \geq 0.5 ,$$

as provided above.

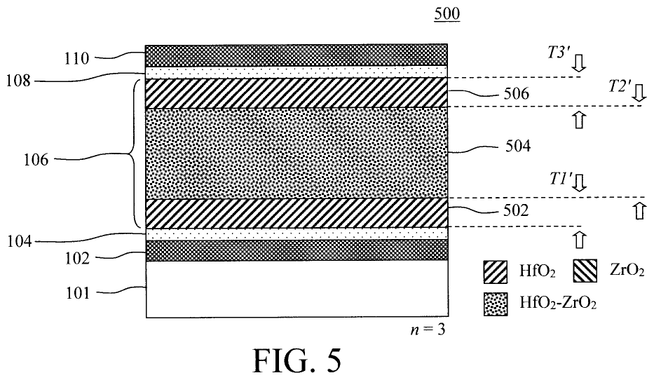

Variations of the above-described configurations are also possible. For instance, with the metal-insulator-metal capacitor 500 shown in FIG. 5, ferroelectric film 106 is configured as multiple layers 502, 504 and 506, i.e., n=3, with layer 502 containing HfO₂, layer 504 containing a mixture of HfO₂ and ZrO₂ (HfO₂—ZrO₂), and layer 506 containing HfO₂. This configuration can be achieved by depositing a layer of HfO₂ on the first buffer layer 104, co-depositing HfO₂ and ZrO₂ (HfO₂—ZrO₂) on the layer of HfO₂, and then depositing another layer of HfO₂ on the HfO₂—ZrO₂ mixture layer, followed by a thermal treatment (see above) to convert the as-deposited amorphous materials to a (e.g., cubic, tetragonal and/or orthorhombic) crystalline phase. FIG. 5 further illustrates how these various component layers of ferroelectric film 106 can be of varying thicknesses. For instance, in this example, layer 502 has a thickness T1′, layer 504 has a thickness T2′ and layer 506 has a thickness T3′, where T2′ is greater than either T1′ or T3′. While, in this example, thickness T′ is equivalent to thickness T3′ (T1′=T3′) this is not a requirement, and embodiments are contemplated herein where thickness T1′ is different from thickness T3′. However, as provided above, the combined thickness of layers 502, 504 and 506 is preferably up to about 10 nm, e.g., from about 4 nm to about 8 nm and ranges therebetween.

Of course, in accordance with the present techniques, the number of layers n making up the ferroelectric film 106 can vary from what is shown in the figures, with each of the layers containing HfO₂, ZrO₂, or a mixture (HfO₂—ZrO₂) thereof. In one exemplary embodiment, n=x, where x is from 1 to 5 and ranges therebetween.

The capacitance per unit area of the present capacitor designs can be further increased by employing a three-dimensional capacitor structure, where the above-described metal-insulator-metal capacitors are stacked one on top of another. See, for example, stacked capacitor 601 shown in FIG. 6. Advantageously, employing a stacked three-dimensional capacitor structure increases capacitance without expanding the overall footprint of the device. As shown in FIG. 6, stacked capacitor 601 includes a first metal-insulator-metal capacitor 600A and a second metal-insulator-metal capacitor 600B stacked on top of the first metal-insulator-metal capacitor 600A.

First metal-insulator-metal capacitor 600A and second metal-insulator-metal capacitor 600B generally represent any of the above-described metal-insulator-metal capacitor designs, however in this stacked configuration they share a common electrode. Namely, first metal-insulator-metal capacitor 600A includes a (first) electrode 602, a first buffer layer 604A disposed on the electrode 602, a ferroelectric film 606A disposed on the first buffer layer 604A, a second buffer layer 608A disposed on the ferroelectric film 606A, and a shared (second) electrode 610 disposed on the second buffer layer 608A. Shared electrode 610 is the second/top electrode of first metal-insulator-metal capacitor 600A and the first/bottom electrode of second metal-insulator-metal capacitor 600B. Namely, second metal-insulator-metal capacitor 600B includes shared (first) electrode 610, a first buffer layer 604B disposed on shared electrode 610, a ferroelectric film 606B disposed on the first buffer layer 604B, a second buffer layer 608B disposed on the ferroelectric film 606B, and a (second) electrode 612 disposed on the second buffer layer 608B.

Any of the above-described configurations of the first/second buffer layers 104 and 108 of metal-insulator-metal capacitor 100 can be employed for first buffer layers 604A/604B and second buffer layers 608A/608B. Likewise, any of the above-described configurations of the ferroelectric film 106 of metal-insulator-metal capacitor 100 can be employed for ferroelectric film 606A/606B. Thus, ferroelectric film 606A/606B can include at least a first dielectric material and a second dielectric material such as HfO₂ and ZrO₂, respectively, in a (e.g., cubic, tetragonal and/or orthorhombic) crystalline phase having a higher dielectric constant κ value than either the first buffer layer or the second buffer layer, which are combined amongst one or more layers, as described in detail above. Further, while first metal-insulator-metal capacitor 600A and second metal-insulator-metal capacitor 600B can be configured alike, this is not a requirement, and embodiments are contemplated herein where first metal-insulator-metal capacitor 600A differs from second metal-insulator-metal capacitor 600B.

The electrical bias polarity of the first metal-insulator-metal capacitor 600A is opposite to the electrical bias polarity of the second metal-insulator-metal capacitor 600B, as indicated by arrows 614 and 616, respectively. By way of example only, this opposing polarity can be achieved by grounding the shared electrode 610 and electrically biasing electrodes 602 and 612. See FIG. 6.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A capacitor, comprising:
a first electrode;
a second electrode; and
multiple dielectric layers present in between the first electrode and the second electrode, the multiple dielectric layers comprising a first buffer layer disposed on the first electrode, a ferroelectric film disposed on the first buffer layer, and a second buffer layer disposed on the ferroelectric film, wherein the ferroelectric film comprises a combination of at least a first dielectric material and a second dielectric material having a higher dielectric constant κ value than either the first buffer layer or the second buffer layer.

2. The capacitor of claim 1, wherein the first buffer layer and the second buffer layer each has a thickness of from about 4 angstroms (Å) to about 10 Å.

3. The capacitor of claim 1, wherein the ferroelectric film has a thickness of from about 4 nanometers (nm) to about 8 nm.

4. The capacitor of claim 1, wherein the first buffer layer and the second buffer layer each comprises aluminum oxide (Al₂O₃).

5. The capacitor of claim 1, wherein the first dielectric material and the second dielectric material are each selected from a group consisting of: hafnium oxide (HfO₂), zirconium oxide (ZrO₂), and combinations thereof.

6. The capacitor of claim 1, wherein the first dielectric material and the second dielectric material are in a crystalline phase selected from a group consisting of: a cubic phase, a tetragonal phase, an orthorhombic phase, and combinations thereof.

7. The capacitor of claim 1, wherein the combination of the first dielectric material and the second dielectric material comprises the first dielectric material and the second dielectric material being present within a common layer.

8. The capacitor of claim 1, wherein the combination of the first dielectric material and the second dielectric material comprises the first dielectric material and the second dielectric material being present in multiple layers.

9. A capacitor, comprising:
a first electrode;
a second electrode; and
multiple dielectric layers present in between the first electrode and the second electrode, the multiple dielectric layers comprising a first buffer layer disposed on the first electrode, a ferroelectric film disposed on the first buffer layer, and a second buffer layer disposed on the ferroelectric film, wherein the first buffer layer and the second buffer layer each comprises Al₂O₃, and wherein the ferroelectric film comprises both HfO₂ and ZrO₂.

10. The capacitor of claim 9, wherein the first buffer layer and the second buffer layer each has a thickness of from about 4 Å to about 10 Å.

11. The capacitor of claim 9, wherein the ferroelectric film has a thickness of from about 4 nm to about 8 nm.

12. The capacitor of claim 9, wherein the ferroelectric film comprises HfO₂ and ZrO₂ in a crystalline phase selected from a group consisting of: a cubic phase, a tetragonal phase, an orthorhombic phase, and combinations thereof.

13. The capacitor of claim 9, wherein the ferroelectric film comprises HfO₂ and ZrO₂ combined within a common layer.

14. A capacitor, comprising:
a first electrode;
a second electrode; and
multiple dielectric layers present in between the first electrode and the second electrode, the multiple dielectric layers comprising a first buffer layer disposed on the first electrode, a ferroelectric film disposed on the first buffer layer, and a second buffer layer disposed on the ferroelectric film, wherein the first buffer layer and the second buffer layer each comprises Al₂O₃, and wherein the ferroelectric film comprises HfO₂ and ZrO₂ present in multiple layers.

15. The capacitor of claim 14, wherein the ferroelectric film comprises at least a HfO₂ layer and a ZrO₂ layer.

16. The capacitor of claim 14, wherein the ferroelectric film comprises:
a first HfO₂ layer disposed on the first buffer layer;
a ZrO₂ layer disposed on the first HfO₂ layer; and
a second HfO₂ layer disposed on the ZrO₂ layer.

17. The capacitor of claim 16, wherein the first HfO₂ layer has a thickness T1, the ZrO₂ layer has a thickness T2, and the second HfO₂ layer has a thickness T3, wherein T2 is greater than either T1 or T3.

18. The capacitor of claim 14, wherein the ferroelectric film has a thickness of from about 4 nm to about 8 nm.

19. The capacitor of claim 14, wherein the ferroelectric film comprises HfO₂ and ZrO₂ in a crystalline phase selected from a group consisting of: a cubic phase, a tetragonal phase, an orthorhombic phase, and combinations thereof.

20. A capacitor device, comprising:
a first capacitor; and
a second capacitor stacked on top of the first capacitor,
wherein the first capacitor and the second capacitor each comprises a first electrode, a second electrode, and multiple dielectric layers present in between the first electrode and the second electrode, wherein the second electrode of the first capacitor is shared with the first electrode of the second capacitor, wherein the multiple dielectric layers comprise a first buffer layer disposed on the first electrode, a ferroelectric film disposed on the first buffer layer, and a second buffer layer disposed on the ferroelectric film, and wherein the ferroelectric film comprises a combination of at least a first dielectric material and a second dielectric material having a higher dielectric constant κ value than either the first buffer layer or the second buffer layer.

21. The capacitor device of claim 20, wherein the first buffer layer and the second buffer layer each comprises Al₂O₃.

22. The capacitor device of claim 20, wherein the first dielectric material and the second dielectric material are each selected from a group consisting of: HfO₂, ZrO₂, and combinations thereof.

23. The capacitor device of claim 20, wherein the first dielectric material and the second dielectric material are in a crystalline phase selected from a group consisting of: a cubic phase, a tetragonal phase, an orthorhombic phase, and combinations thereof.

24. A method of forming a capacitor, the method comprising:
forming multiple dielectric layers on a first electrode by depositing a first buffer layer on the first electrode, depositing a ferroelectric film on the first buffer layer, and depositing a second buffer layer on the ferroelectric film, wherein the ferroelectric film comprises a combination of at least a first dielectric material and a second dielectric material having a higher dielectric constant κ value than either the first buffer layer or the second buffer layer; and
forming a second electrode on the second buffer layer.

25. The method of claim 24, further comprising:
converting the first dielectric material and the second dielectric material from an as-deposited amorphous form to a crystalline phase selected from a group consisting of: a cubic phase, a tetragonal phase, an orthorhombic phase, and combinations thereof.
